(19) United States
(12) Patent Application Publication
(10) Pub. No.: US 2026/0204526 A1
(43) Pub. Date: Jul. 16, 2026

(54) SUBSTRATE PROCESSING APPARATUS, METHOD OF PROCESSING SUBSTRATE, METHOD OF MANUFACTURING SEMICONDUCTOR DEVICE, AND RECORDING MEDIUM

(71) Applicant: KOKUSAI ELECTRIC CORPORATION, Tokyo (JP)

(72) Inventors: Koichiro HARADA, Toyama-shi (JP); Katsuhiko YAMAMOTO, Toyama-shi (JP); Masaki MUROBAYASHI, Toyama-shi (JP); VAN CHIEU NGUYEN, Toyama-shi (JP)

(73) Assignee: KOKUSAI ELECTRIC CORPORATION, Tokyo (JP)

(21) Appl. No.: 19/567,264

(22) Filed: Mar. 16, 2026

Related U.S. Application Data
(63) Continuation of application No. PCT/JP2023/036323, filed on Oct. 5, 2023.

(51) Int. Cl. H01J 37/32

(52) U.S. Cl. CPC H01J 37/32834; H01J 37/3211; H01J 37/32449; H01J 2237/338

(57) ABSTRACT

A technique that includes : a process chamber in which a substrate is processed with a gas; a plasma generator configured to convert the gas into a plasma state; a supply pipe installed at an upstream side of the process chamber; an exhaust pipe installed at a downstream side of the process chamber; a valve installed at a downstream side of the exhaust pipe; and an attenuator configured to attenuate an energy of the gas in the plasma state, the attenuator being installed at the exhaust pipe at a position closer to the valve than the process chamber, or installed at an upstream side of a connection between the supply pipe and the process chamber.

### CROSS-REFERENCE TO RELATED APPLICATION

This application is a Bypass Continuation Application of PCT International Application No. PCT/JP2023/036323, filed on October 5, 2023, the disclosure of which is incorporated herein in its entirety by reference.

### TECHNICAL FIELD

The present disclosure relates to a substrate processing apparatus, a method of processing a substrate, a method of manufacturing a semiconductor device, and a recording medium.

### BACKGROUND

In the related art, in a substrate processing apparatus used in a process of manufacturing a semiconductor device, a predetermined process may be performed on a substrate by using a plasma-excited gas.

### SUMMARY

Some embodiments of the present disclosure provide a technique capable of suppressing deterioration of apparatus constituent members caused by plasma.

According to some embodiments of the present disclosure, there is provided a technique that includes: a process chamber in which a substrate is processed with a gas; a plasma generator configured to convert the gas into a plasma state; a supply pipe installed at an upstream side of the process chamber; an exhaust pipe installed at a downstream side of the process chamber; a valve installed at a downstream side of the exhaust pipe; and an attenuator configured to attenuate an energy of the gas in the plasma state, the attenuator being installed at the exhaust pipe at a position closer to the valve than the process chamber, or installed at an upstream side of a connection between the supply pipe and the process chamber.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a substrate processing apparatus according to a first embodiment of the present disclosure, in which a portion of a process furnace is shown in a vertical cross-sectional view...

FIG. 2 is a schematic diagram of a controller in the substrate processing apparatus according to the first embodiment of the present disclosure, in which a control system of the controller is shown in a block diagram.

FIG. 3 is a flowchart showing a substrate processing process according to the first embodiment of the present disclosure.

FIGS. 4A and 4B are explanatory diagrams showing an example of a substrate processed in the substrate processing process according to the first embodiment of the present disclosure, FIG. 4A is a cross-sectional view of the substrate with a recess formed therein, and FIG. 4B is a cross-sectional view of the substrate when the substrate shown in FIG. 4A is subjected to the substrate processing process.

FIG. 5 is a configuration diagram of an exhauster in the substrate processing apparatus according to the first embodiment of the present disclosure, in which a portion G in FIG. 1 is shown in an enlarged view.

FIGS. 6A and 6B are explanatory diagrams showing an example of a configuration of an attenuator in the substrate processing apparatus according to the first embodiment of the present disclosure, FIG. 6A is a perspective view showing a schematic configuration of the attenuator, and FIG. 6B is a side cross-sectional view showing a cross-sectional configuration of the attenuator.

FIG. 7 is an explanatory diagram showing another example of the configuration of the attenuator in the substrate processing apparatus according to the first embodiment of the present disclosure.

FIGS. 8A and 8B are explanatory diagrams showing yet another example of the configuration of the attenuator in the substrate processing apparatus according to the first embodiment of the present disclosure, FIG. 8A is a schematic diagram showing a schematic configuration of the attenuator, and FIG. 8B is a schematic diagram showing another schematic configuration of the attenuator.

FIG. 9 is a schematic configuration diagram of a substrate processing apparatus according to a second embodiment of the present disclosure, in which a portion of a process furnace is shown in a vertical cross-sectional view.

FIG. 10 is a configuration diagram of main components of a substrate processing apparatus according to a third embodiment of the present disclosure, showing a schematic configuration of a plasma generator.

FIG. 11 is a configuration diagram of main components of a substrate processing apparatus according to a fourth embodiment of the present disclosure, showing a schematic configuration of a gas supplier.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described above in detail so as not to unnecessarily obscure aspects of the various embodiments.

Hereinafter, embodiments of the present disclosure will be described with reference to the drawings. Drawings used in the following description are schematic, and dimensional relationships, ratios, etc. of components shown in the drawings may not match actual ones. Furthermore, dimensional relationships, ratios, etc. of components may not correspond to one another among multiple drawings.

### First Embodiment

First, a first embodiment of the present disclosure will be described in detail.

### 1. SUBSTRATE PROCESSING APPARATUS

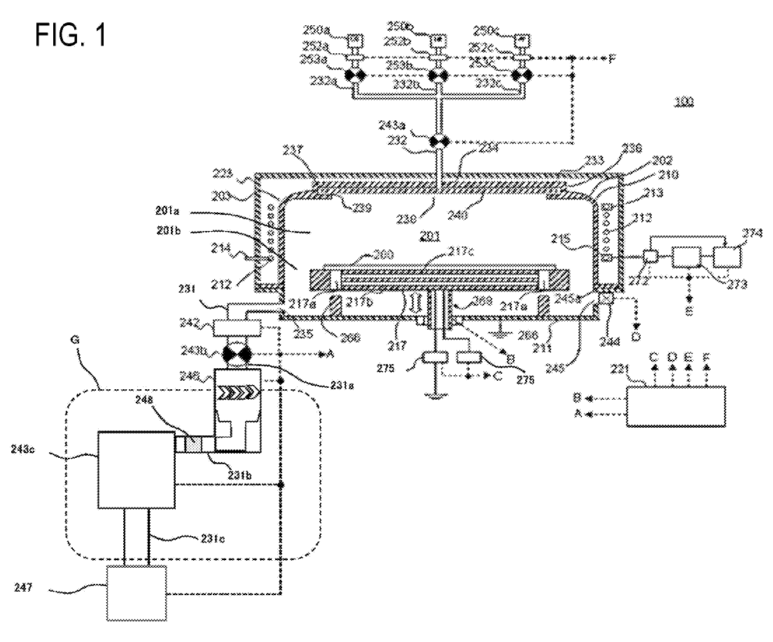

The substrate processing apparatus according to the first embodiment will be described below with reference to FIG. 1. FIG. 1 is a schematic configuration diagram of the substrate processing apparatus according to the first embodiment.

The substrate processing apparatus 100 according to the present embodiment is configured to mainly perform an oxidation process on a film formed on a surface of a wafer 200 serving as a substrate.

### Process Chamber

The substrate processing apparatus 100 includes a process furnace 202 in which a wafer 200 is plasma processed. The process furnace 202 includes a process container 203 that constitutes a process chamber 201. The process container 203 includes a dome-shaped upper container 210, which serves as a first container, and a bowl-shaped lower container 211, which serves as a second container. The process chamber 201 is formed by the upper container 210 being placed over the lower container 211. The upper container 210 is made of, for example, a non-metallic material such as aluminum oxide (A120₃) or quartz (SiO2), while the lower container 211 is made of, for example, aluminum (Al).

A gate valve 244 is installed at a lower sidewall of the lower container 211. When the gate valve 244 is open, a transfer mechanism (not shown) may be used to load the wafer 200 into the process chamber 201 or unload the wafer 200 out of the process chamber 201 via a loading/unloading port 245. When the gate valve 244 is closed, the gate valve 244 is configured to function as a partition valve configured to maintain airtightness in the process chamber 201.

The process chamber 201 includes a plasma generation space 201 a around which a resonance coil 212 is installed, and a substrate processing space 201b which is in fluid communication with the plasma generation space 201 a and in which the wafer 200 is processed. The plasma generation space 201a is a space in which plasma is generated, and refers to a space within the process chamber which is provided above a lower end of the resonance coil 212 and below an upper end of the resonance coil 212. On the other hand, the substrate processing space 201b is a space in which the wafer 200 is processed by using plasma, and refers to a space below the lower end of the resonance coil 212. In the present embodiment, the plasma generation space 201a and the substrate processing space 201b are configured such that diameters of the plasma generation space 201a and the substrate processing space 201b are substantially the same in the horizontal direction.

### Susceptor

A susceptor 217 serving as a substrate mounting stage configured to mount the wafer 200 thereon is located at a center of a bottom of the process chamber 201. The susceptor 217 is made of, for example, a non-metallic material such as aluminum nitride (AIN), ceramics, or quartz, and is configured to reduce metal contamination of films formed on the wafer 200.

A heater 217b serving as a heating mechanism is integrally embedded inside the susceptor 217. The heater 217b is configured to be capable of heating the surface of the wafer 200 to, for example, about 25 degrees C to 750 degrees C when electric power is supplied thereto.

The susceptor 217 is electrically insulated from the lower container 211. An impedance regulation electrode 217c is installed inside the susceptor 217 to further improve uniformity of density of plasma generated over the wafer 200 mounted on the susceptor 217, and is grounded via an impedance variator 275 serving as an impedance regulator. The impedance variator 275 is constituted by a coil and a variable capacitor. By regulating the impedance variator 275, a potential (bias voltage) of the wafer 200 can be controlled via the impedance regulation electrode 217c and the susceptor 217.

In the susceptor 217, there is installed a susceptor elevator 268 including a driver configured to raise or lower the susceptor. Through-holes 217a are provided at the susceptor 217 , and wafer push-up pins 266 are installed at a bottom surface of the lower container 211. When the susceptor 217 is lowered by the susceptor elevator 268, the wafer push-up pins 266 are configured to pass through the through-holes 217a without being in contact with the susceptor 217. A substrate mounting stage according to the present embodiment is mainly constituted by the susceptor 217, the heater 217b, and the impedance regulation electrode 217c.

### Gas Supplier

A gas supply head 236 is installed above the process chamber 201, i.e., at the top of the upper container 210. The gas supply head 236 includes a cap-shaped lid 233, a gas introduction port 234, a buffer chamber 237, an opening 238, a shielding plate 240, and a gas discharge port 239, and is configured to be capable of supplying processing gases into the process chamber 201. The buffer chamber 237 functions as a dispersion space configured to disperse the processing gases introduced through the gas introduction port 234.

A downstream end of the gas supply pipe 232 is connected to the gas introduction port 234. That is, the gas supply pipe 232 is installed at the upstream side of the process chamber 201. A downstream end of an oxygen-containing gas supply pipe 232a configured to supply an oxygen (O)-containing gas, a downstream end of a hydrogen-containing gas supply pipe 232b configured to supply a hydrogen (H)-containing gas, and an inert gas supply pipe 232c configured to supply an inert gas are connected to an upstream end of the gas supply pipe 232 so as to merge. An O-containing gas supply source 250a, a mass flow controller (MFC) 252a as a flow rate controller, and a valve 253a as an on-off valve are installed sequentially from the upstream side at the oxygen-containing gas supply pipe 232a. A H-containing gas supply source 250b, a MFC 252b, and a valve 253b are installed sequentially from the upstream side at the hydrogen-containing gas supply pipe 232b. An inert gas supply source 250c, a MFC 252c, and a valve 253c are installed sequentially from the upstream side at the inert gas supply pipe 232c. A valve 243a is installed at a downstream side of a position where the oxygen-containing gas supply pipe 232a, the hydrogen-containing gas supply pipe 232b, and the inert gas supply pipe 232c merge, and is connected to an upstream end of the gas introduction port 234. By opening or closing the valves 253a, 253b, 253c, and 243a, processing gases such as an O-containing gas, a H-containing gas, and an inert gas can be supplied into the process chamber 201 via the gas supply pipes 232a, 232b, and 232c while regulating flow rates of the respective gases by using the MFCs 252a, 252b, and 252c.

An oxygen-containing gas supply system according to the present embodiment is mainly constituted by the oxygen-containing gas supply pipe 232a, the MFC 252a, and the valve 253a. Furthermore, a hydrogen-containing gas supply system according to the present embodiment is constituted by the gas supply pipe 232, the hydrogen-containing gas supply pipe 232b, the MFC 252b, and the valve 253b. In addition, an inert gas supply system according to the present embodiment is constituted by the gas supply pipe 232, the inert gas supply pipe 232c, the MFC 252c, and the valve 253c.

Furthermore, a processing gas supplier (processing gas supply system) according to the present embodiment is mainly constituted by either the oxygen-containing gas supply system or the hydrogen-containing gas supply system, or a combination thereof. The processing gas supplier may include any one of the gas supply head 236 (the lid 233, the gas introduction port 234, the buffer chamber 237, the opening 238, the shielding plate 240, and the gas discharge port 239), the MFCs 252a, 252b, and 252c, and the inert gas supply system, or a combination thereof.

### Exhauster

A gas exhaust port 235 through which the processing gases are exhausted from the interior of the process chamber 201 is installed at the sidewall of the lower container 211. An upstream end of the gas exhaust pipe 231 is connected to the gas exhaust port 235. In other words, the gas exhaust pipe 231 is installed at a downstream side of the process chamber 201 and is configured to be in fluid communication with an interior of the process chamber 201 via the gas exhaust port 235.

An auto pressure controller (APC) valve 242 as a pressure regulator (pressure regulation unit), a sub-valve 243b as an on-off valve, a first pump 246 as a vacuum exhauster, a main valve 243c as an on-off valve, and a second pump 247 as a vacuum exhauster are installed sequentially from the upstream side at the gas exhaust pipe 231. The main valve 243c is installed at a downstream side of the gas exhaust pipe 231 (i.e., at a side close to the second pump 247 located at a downstream end of the gas exhaust pipe 231).

The first pump 246 is configured to create a high vacuum or an ultra-high vacuum state inside the process chamber 201 and is constituted by, for example, a turbomolecular pump. The sub-valve 243b functions as an on-off valve associated with the first pump 246 and is constituted by, for example, a butterfly valve. The second pump 247 functions as a rough exhaust vacuum pump configured to perform an exhaust from an atmospheric pressure so as to assist an operation of the first pump 246 and is constituted by, for example, a dry vacuum pump. The main valve 243c functions as an on-off valve associated with the second pump 247 and is constituted by, for example, a piston valve that is configured to be opened or closed by a slide of a valve body.

In this way, at least the first pump 246, the main valve 243c, and the second pump 247 are installed at the gas exhaust pipe 231. As a result, the gas exhaust pipe 231 includes a first exhaust pipe 231 a configured to connect the gas exhaust port 235 and the first pump 246, a second exhaust pipe 231b configured to connect the first pump 246 and the main valve 243c, and a third exhaust pipe 231c configured to connect the main valve 243c and the second pump 247.

Furthermore, an attenuator 248 is installed at the gas exhaust pipe 231 at a position closer to the main valve 243c than the process chamber 201. More specifically, the attenuator 248 is installed at the second exhaust pipe 231b. The attenuator 248 will be described in detail later.

An exhauster according to the present embodiment is mainly constituted by the gas exhaust port 235, the gas exhaust pipe 231, and the sub-valve 243b. The exhauster may also include the APC valve 242, the first pump 246, and the main valve 243c. Furthermore, the exhauster may include the second pump 247.

### Plasma Generator

A spiral resonance coil 212 is installed as a first electrode at an outer periphery of the process chamber 201, i.e., outside the sidewall of the upper container 210, so as to surround the process chamber 201. Connected to the resonance coil 212 are a RF sensor 272, a high- frequency power supply 273, and a matcher 274 configured to match an impedance and an output frequency of the high-frequency power supply 273.

The high-frequency power supply 273 supplies high-frequency power (RF power) to the resonance coil 212. The RF sensor 272 is installed at an output side of the high-frequency power supply 273 to monitor information on a forward wave and a reflected wave of the high-frequency wave supplied. The reflected wave power monitored by the RF sensor 272 is input to a matcher 274, which controls the impedance of the high-frequency power supply 273 and the frequency of the output high-frequency power, based on the information on the reflected wave input from the RF sensor 272, so as to minimize the reflected wave.

A winding diameter, a winding pitch, and the number of turns of the resonance coil 212 are set so as to resonate at a certain wavelength to form a standing wave with a predetermined wavelength. That is, an electrical length of the resonance coil 212 is set to a length corresponding to an integer multiple (one time, two times, and the like) of one wavelength at a predetermined frequency of the high-frequency power supplied from the high-frequency power supply 273.

Both ends of the resonance coil 212 are electrically grounded, and at least one end of the resonance coil is grounded via a movable tap 213 to fine-tune the electrical length of the resonance coil when an apparatus is initially installed or when processing conditions are changed. Reference numeral 214 in FIG. 1 denotes a fixed ground on the other side. A position of the movable tap 213 is regulated such that resonance characteristics of the resonance coil 212 are substantially equal to those of the high-frequency power supply 273. Furthermore, a power supply is constituted between the grounded ends of the resonance coil 212 by a movable tap 215 to fine-tune the impedance of the resonance coil 212 when the apparatus is initially installed or when the processing conditions are changed. The resonance coil 212 includes a variable ground and a variable power supply, which makes it easier to regulate the resonance frequency and load impedance of the process chamber 201.

A plasma generator (plasma generation mechanism) according to the present embodiment is mainly constituted by the resonance coil 212, the RF sensor 272, and the matcher 274. The plasma generator may also include the high-frequency power supply 273.

According to this configuration, the resonance coil 212 according to the present embodiment is supplied with high-frequency power at an actual resonance frequency of the resonance coil, including plasma (or is supplied with high-frequency power such that an actual impedance of the resonance coil, including plasma, is matched). Therefore, a standing wave is formed in which a phase voltage and an anti-phase voltage are always canceled out. When the electrical length of the resonance coil 212 is the same as a wavelength of the high-frequency power, the highest phase current is generated at an electrical midpoint of the coil (a node where the voltage is zero). Therefore, near the electrical midpoint, there is almost no capacitive coupling with a process chamber wall or the susceptor 217, and a donut-shaped induction plasma with an extremely low electrical potential is formed.

That is, in the present embodiment, the plasma generator is configured to include the resonance coil 212 capable of generating plasma within the process chamber 201. By supplying high-frequency power to the resonance coil 212, inductively coupled plasma (ICP) is generated.

### Control Part

The substrate processing apparatus 100 includes a controller 221 that functions as a control part (control means or unit) configured to control an operation of each component of the substrate processing apparatus 100.

The controller 221 is configured to control the APC valve 242, the valves 243b and 243c, the first pump 246, and the second pump 247 via signal line A, control the susceptor elevator 268 via signal line B, control the heater power regulator 276 and the impedance variator 275 via signal line C, control the gate valve 244 via signal line D, control the RF sensor 272, the high- frequency power supply 273, and the matcher 274 via signal line E, and control the MFCs 252a to 252c and the valves 253a to 253c and 243a via signal line F.

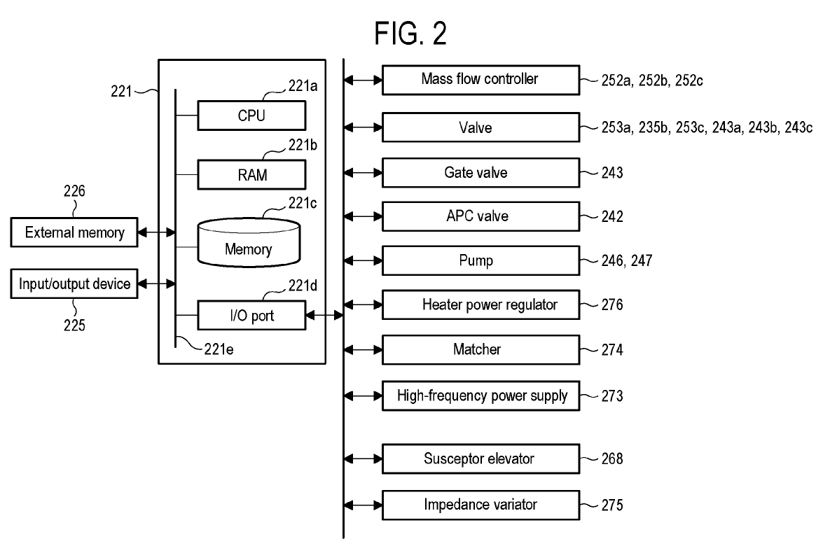

FIG. 2 is a block diagram showing a schematic configuration of the controller 221. As shown in FIG. 2, the controller 221, which is a control part (control means or unit), is constituted as a computer equipped with a central processing unit (CPU) 221 a, a random access memory (RAM) 221b, a memory 221c, and an I/O port 221d. The RAM 221b, the memory 221c, and the I/O port 221 d are configured to being capable of exchanging data with the CPU 221 a via an internal bus 221 e. An input/output device 225 constituted as, for example, a touch panel or a display is connected to the controller 221.

The memory 221c is constituted by, for example, a flash memory, a hard disk drive (HDD), etc. The memory 221 c readably stores a control program that controls the operation of the substrate processing apparatus, a program recipe describing procedures and conditions for substrate processing (described later), etc. The process recipe is a combination that causes the controller 221 to execute respective procedures in a substrate processing process (described later) to obtain a predetermined result. The process recipe functions as a program. Hereinafter, the program recipe, the control program, etc. are generally and simply referred to as a program. When the term "program" is used in the present disclosure, it may include the program recipe, the control program, or both. The RAM 221b is constituted as a memory area (work area) in which programs, data, etc. read by the CPU 221 a are temporarily held.

The I/O port 221d is connected to the MFCs 252a to 252c, the valves 253a to 253c, 243a, 243b and 243c, the gate valve 244, the APC valve 242, the first pump 246, the second pump 247, the RF sensor 272, the high-frequency power supply 273, the matcher 274, the susceptor elevator 268, the impedance variator 275, the heater power regulator 276, and the like.

The CPU 221 a is configured to read a control program from the memory 221 c and execute the control program, and is also configured to read a process recipe from the memory 221 c in response to an input of an operation command from the input/output device 225, etc. The CPU 221 a is configured to be capable of controlling, in accordance with the contents of the process recipe thus read, an operation of regulating a degree of valve opening of the APC valve 242, an operation of opening or closing the valves 243b and 243c, and start and stop of the first pump 246 and the second pump 247 via the I/O port 221 d and the signal line A, an operation of raising or lowering the susceptor elevator 268 via the signal line B, an operation of regulating an amount of electric power supplied to the heater 217b by the heater power regulator 276 (temperature regulating operation) and an operation of regulating an impedance value by the impedance variator 275 via the signal line C, an operation of opening or closing the gate valve 244 via the signal line D, operations of the RF sensor 272, the matcher 274 and the high- frequency power supply 273 via the signal line E, and flow rate regulating operations for various gases by the MFCs 252a to 252c and operations of opening or closing the valves 253a to 253c and 243a via the signal line F.

The controller 221 may be configured by installing the above-mentioned program stored in an external memory 226 (e.g., a magnetic tape, a magnetic disk such as a flexible disk or a hard disk, an optical disc such as a CD or a DVD, a magneto-optical disc such as a MO, or a semiconductor memory such as a USB memory or a memory card) into a computer. The memory 221 c and the external memory 226 are constituted as a computer-readable recording medium. Hereinafter, these will be generally and simply referred to as a recording medium. In the present disclosure, when the term "recording medium" is used, it may include the memory 221 c, the external memory 226, or both. The program may be provided to the computer by using a communication means or unit such as the Internet or a dedicated line, instead of using the external memory 226.

### 2. Substrate Processing Process

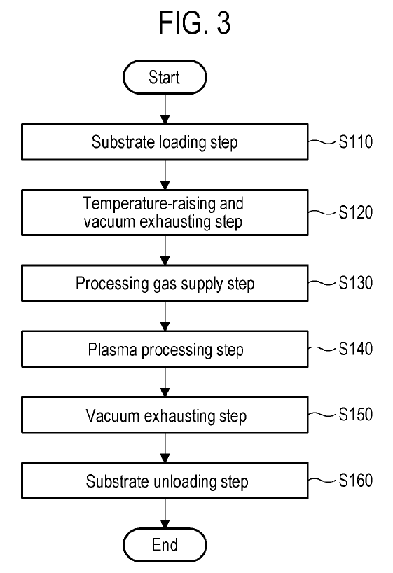

Next, a substrate processing process according to the first embodiment of the present disclosure will be described mainly with reference to FIG. 3. FIG. 3 is a flowchart illustrating the substrate processing process according to the first embodiment of the present disclosure. The substrate processing process according to the first embodiment is performed as a process of manufacturing a semiconductor device such as a flash memory or the like by using the above-described substrate processing apparatus 100. In the following description, an operation of each component of the substrate processing apparatus 100 is controlled by the controller 221.

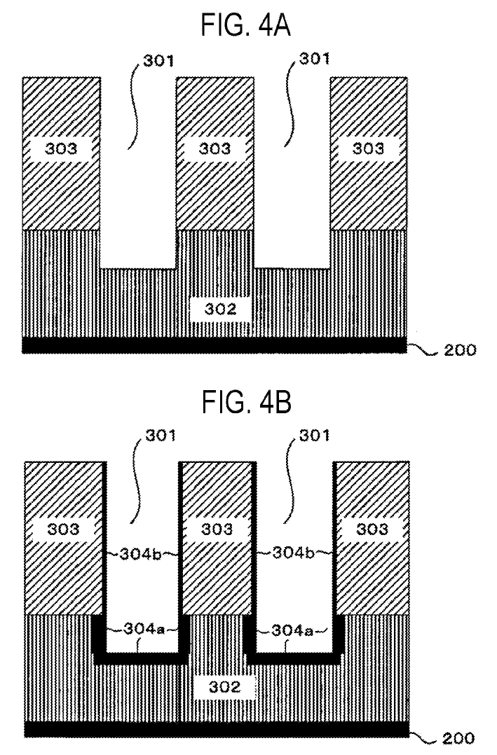

In this substrate processing process, processing is performed on a wafer 200, for example, as shown in FIG. 4A. FIGS. 4A and 4B are explanatory diagrams showing an example of a substrate processed in the substrate processing process. Specifically, as shown in FIG. 4A, a recess 301 is formed on the wafer 200 as a substrate in advance with a silicon (Si) film 302 and a silicon nitride (SiN) film 303 formed on at least the surface thereof. That is, in the wafer 200 processed in this substrate processing process, the Si film 302 and the SiN film 303 are exposed inside the recess 301 formed on the wafer 200, and the Si film 302 forms a bottom of the recess 301. The recess 301 is, for example, a trench or a hole, and an aspect ratio of the recess 301 is 20 or more. In this substrate processing process, an oxidation process is performed on the recess 301 by using plasma. The Si film 302 is made of at least one selected from the group of monocrystalline silicon (c-Si), amorphous silicon (a-Si), and polycrystalline silicon (Poly-Si).

In the present disclosure, when the word "substrate" is used, it may mean "a substrate itself' or "a laminated body (aggregate) of a substrate and a predetermined layer, film or the like formed on its surface" (i.e., it may mean a substrate including a predetermined layer, film, or the like formed on the surface thereof). In addition, when the words "a surface of a substrate" are used in the present disclosure, it may mean "a surface (exposed surface) of the substrate itself' or "a surface of a predetermined layer, film, or the like formed on a substrate, i.e., an outermost surface of a substrate as a laminated body." Therefore, when it is written in the present disclosure that "a predetermined gas is supplied to a substrate," it may mean "directly supplying a predetermined gas to a surface (exposed surface) of a substrate itself' or "supplying a predetermined gas to a layer, film, or the like formed on a substrate, i.e., to an outermost surface of a substrate as a laminated body." In addition, in the present disclosure, it may mean "forming a predetermined layer (or film) on a layer, film, etc. formed on a substrate, i.e., on an outermost surface of a substrate as a laminate." In addition, the term "substrate" used herein may be synonymous with the term "wafer." In that case, in the above description, the "substrate" may be replaced with the "wafer."

### Substrate Loading Step S 110

As shown in FIG. 3, in this substrate processing process, a wafer 200 is first loaded into the process chamber 201.

Next, the gate valve 244 is opened, and the wafer 200 is loaded into the process chamber 201 from a vacuum transfer chamber adjacent to the process chamber 201 by using a wafer transfer mechanism (not shown). The loaded wafer 200 is supported on an upper surface of the susceptor 217. Furthermore, the wafer transfer mechanism is retracted to the outside of the process chamber 201, and the gate valve 244 is closed to hermetically seal the process chamber 201.

### Temperature-raising and Vacuum exhausting Step S 120

Next, the wafer 200 loaded into the process chamber 201 is temperature-raised. The heater 217b is preheated, and the wafer 200 is held on the susceptor 217 including the heater 217b embedded therein, thereby heating the wafer 200 to a predetermined temperature, for example, within a range of 150 to 700 degrees C. In this case, the wafer 200 is heated to 700

degrees C. While the wafer 200 is being temperature-raised, the interior of the process chamber 201 is vacuum-exhausted by the vacuum pump 246 via the gas exhaust pipe 231, thereby maintaining an internal pressure of the process chamber 201 at a predetermined value. The vacuum pump 246 is operated at least until the substrate unloading process S160 described below is completed. In the present disclosure, expression of a numerical range such as "150 to 700 degrees C" means that both of a lower limit and an upper limit are included in that range. For example, "150 to 700 degrees C" means "150 degrees C or higher and 700 degrees C or lower." The same applies to other numerical ranges.

### Processing Gas Supply Step S130

Next, the supply of a mixed gas of an O-containing gas and a H-containing gas as a processing gas is started. That is, the mixed gas of the O-containing gas and the H-containing gas as the processing gas is supplied into the process chamber 201 in which the wafer 200 is accommodated. Specifically, the valves 253a and 253b are opened, and the supply of the O- containing gas and the H-containing gas into the process chamber 201 is started while controlling flow rates thereof with the MFCs 252a and 252b. At this time, the flow rate of the O-containing gas is set to a predetermined value, for example, within a range of 10 to 50,000 sccm, specifically 10 to 5,000 sccm. The flow rate of the H-containing gas is also set to a predetermined value, for example, within a range of 10 to 50,000 sccm, specifically 10 to 5,000 sccm.

A ratio between O and H contained in the mixed gas of the O-containing gas and the H- containing gas, which is the processing gas, is regulated by controlling a flow rate ratio between the O-containing gas and the H-containing gas. This makes it possible to easily control the ratio between O and H contained in the processing gas. The ratio between O and H is the ratio between the number of O atoms and the number of H atoms contained in the processing gas. For example, when a mixed gas of an oxygen gas (02 gas) and a hydrogen gas (H2 gas) is used as the mixed gas of the O-containing gas and the H-containing gas, the flow rate ratio between the O- containing gas and the H-containing gas is the ratio between O and H. The flow rate ratio between the O-containing gas and the H-containing gas is regulated to a value corresponding to a predetermined thickness ratio acquired in advance and stored in the memory 221 c or the external memory 226. By acquiring the flow rate ratio between the O-containing gas and the H- containing gas in advance and storing the same in the memory 221 c or the external memory 226 as described above, it becomes easy to regulate the flow rate ratio between the O-containing gas and the H-containing gas.

At this time, a degree of valve opening of the APC valve 242 is regulated to control the exhaust of the interior of the process chamber 201 so that the internal pressure of the process chamber 201 reaches a predetermined pressure, for example, within a range of 1 to 250 Pa, specifically 50 to 200 Pa, and more specifically about 150 Pa. In this manner, while the interior of the process chamber 201 is appropriately exhausted, the supply of the O-containing gas and the H-containing gas continues until end of a plasma processing step S140 which will be described later.

### Plasma Processing Step S 140

Once the internal pressure of the process chamber 201 is stabilized, application of high- frequency power to the resonance coil 212 is started from the high-frequency power supply 273 via the RF sensor 272. In the present embodiment, the high-frequency power of 13.54 to 27.12 MHz is supplied from the high-frequency power supply 273 to the resonance coil 212. The high- frequency power supplied to the resonance coil 212 is predetermined electric power, for example, within a range of 100 to 5,000 W.

As a result, a high-frequency electric field is formed in the plasma generation space 201 a to which the O-containing gas and the H-containing gas are supplied. This electric field excites donut-shaped induction plasma at the highest plasma density at a height position corresponding to the electrical midpoint of the resonance coil 212 in the plasma generation space 201a. The O- containing gas and the H-containing gas in the plasma state are dissociated to generate reactive species including oxygen active species such as oxygen (O) radicals, oxygen ions and hydroxyl (OH) radicals, and hydrogen active species such as hydrogen (H) radicals and hydrogen ions.

That is, the processing gas, which is a mixed gas of the O-containing gas and the H- containing gas supplied into the process chamber 201, is plasma-excited to generate reactive species such as oxygen active species and hydrogen active species. In this case, by generating reactive species with an oxidizing action such as oxygen active species and reactive species with an oxidation-inhibiting action such as hydrogen active species, it is possible to obtain oxidation selectivity for a Si film and a SiN film.

Furthermore, by performing oxidation by using the active species generated by ICP, which is extremely low in electric potential, it is possible to form an oxide layer with good uniformity on a film formed on the surface of the recess 301 with a high aspect ratio of 20 or more. Moreover, even in a case where the recess 301 is not formed perpendicularly to the surface of the wafer 200, such as when the recess 301 is formed on a surface formed perpendicularly to the surface of the wafer 200, it is possible to form an oxide layer with good uniformity on a film formed on the surface.

That is, as shown in FIG. 4B, a SiO layer 304a with a uniform thickness is formed on the entire exposed surface of the Si film 302 that forms the bottom of the recess 301, and a SiO layer 304b with a uniform thickness is formed on the entire exposed surface of the SiN layer 303 that forms a sidewall surface of the recess 301. In addition, a SiO layer 304a that is thicker than the SiO layer 304b formed on the exposed surface of the SiN film 303 is formed on the exposed surface of the Si film 302 that forms the bottom of the recess 301. That is, the surface of the Si film 304 can be selectively oxidized relative to the surface of the SiN film 303 to form the SiO layer 304a, which is an oxide layer.

Thereafter, after a predetermined processing time, for example, 10 to 300 seconds, elapses, the electric power output from the high-frequency power supply 273 is stopped to stop the plasma discharge in the process chamber 201. In addition, the valves 253a and 253b are closed to stop the supply of the O-containing gas and the H-containing gas into the process chamber 201. Thus, the plasma processing step S140 is ended.

### Vacuum Exhausting Step S 150

After the supply of the O-containing gas and H-containing gas is stopped, the interior of the process chamber 201 is vacuum-exhausted via the gas exhaust pipe 231. Thus, the O- containing gas and H-containing gas in the process chamber 201 and exhaust gases generated by reaction of these gases are exhausted to the outside of the process chamber 201. The degree of valve opening of the APC valve 242 is then regulated to adjust the internal pressure of the process chamber 201 to the same pressure as that in the vacuum transfer chamber (an unloading destination of the wafer 200, not shown) adjacent to the process chamber 201.

### Substrate Unloading Step S 160

Once the internal pressure of the process chamber 201 reaches a predetermined pressure, the susceptor 217 is lowered to a wafer transfer position, and the wafer 200 is supported on the wafer push-up pins 266. The gate valve 244 is then opened, and the wafer 200 is unloaded from the process chamber 201 by using the wafer transfer mechanism. Thus, the substrate processing process according to the present embodiment is ended.

Examples of the O-containing gas may include an 02 gas, an ozone (03) gas, a water vapor (H20 gas), a hydrogen peroxide (H202) gas, a nitric oxide (NO) gas, and a nitrous oxide (N2O) gas. Furthermore, the O-containing gas may be a gas including at least one of these gases. Examples of the H-containing gas may include a H2 gas, a H20 gas, a H202 gas, and a deuterium (D2) gas. The H-containing gas may be a gas including at least one of these gases. The O- containing gas and the H-containing gas may be different gases. For example, the O-containing gas and the H-containing gas may be gases which are different in ratio between the number of O atoms and the number of H atoms per flow rate. The O-containing gas and the H-containing gas may be different in ratio between the number of O atoms and the number of H atoms contained in their respective gas compositions (molecular structures).

### 3. Plasma Attenuation

In the substrate processing process described above, in the plasma processing step S 140, the wafer 200 is processed by using a plasma-excited processing gas. In this case, in a case where the wafer 200 to be processed contains a groove-like portion (specifically, the recess 301) with a high aspect ratio on its surface, a radical energy level may be high. To uniformly process a high-aspect-ratio groove from its top side to its bottom side, radicals may be delivered deep into the groove. However, in a case where the radical energy level is low, the radicals may be deactivated midway through the groove and may fail to reach the bottom of the groove.

Meanwhile, when processing the wafer 200, the gas exhaust from the gas exhaust pipe 231 is controlled to regulate the internal pressure of the process chamber 201 to a predetermined pressure during the time from the start of supply of the processing gas in the processing gas supply step S130 to the end of the plasma processing step S 140. After the plasma processing step S140 is completed, the processing gas inside the process chamber 201 is exhausted from the gas exhaust pipe 231 in the vacuum exhausting step S 150. Therefore, the processing gas in a plasma state flows into the gas exhaust pipe 231 that constitutes the exhauster.

In this case, the processing gas in a plasma state may cause the constituent members of the exhauster to be deteriorated due to influence of the plasma. In particular, it is considered that a degree of deterioration of the constituent members of the exhauster is large when the radical energy level is high.

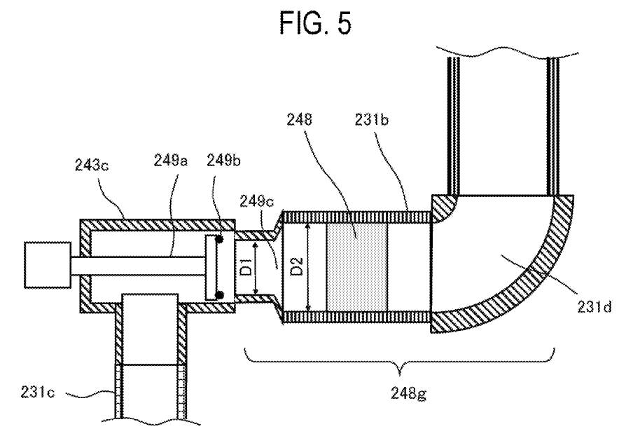

FIG. 5 is a configuration diagram of the exhauster according to the present embodiment, and is an enlarged view of the portion G in FIG. 1. As shown in FIG. 5, in the exhauster, the gas exhaust pipe 231 includes at least a second exhaust pipe 231b and a third exhaust pipe 231c. A main valve 243c is installed between the second exhaust pipe 231b and the third exhaust pipe 231c. The main valve 243c includes a valve body 249a and a seal 249b, which are arranged on an extension line of the gas exhaust pipe 231 (specifically, the second exhaust pipe 231b). An operation of the valve body 249a is controlled by the controller 221. The seal 249b may be, for example, an O-ring. The seal 249b is arranged at a position facing a downstream opening of the gas exhaust pipe 231 (specifically, the second exhaust pipe 231b).

In the exhauster configured as described above, in a case where the processing gas in a plasma state that flowed into the gas exhaust pipe 231 reaches the main valve 243c as it is, the plasma may attack the seal 249b, which may result in deterioration of the seal 249b. In a case where the seal 249b is deteriorated, it may no longer be capable of fully performing its intended function.

However, in the present embodiment, the gas exhaust pipe 231 constituting the exhauster is provided with an attenuator 248. More specifically, the attenuator 248 is installed at a position in the gas exhaust pipe 231 closer to the main valve 243c than the process chamber 201, more specifically, at the second exhaust pipe 231b. In other words, the attenuator 248 is installed at least upstream of the main valve 243c.

The attenuator 248 attenuates an energy of the processing gas in a plasma state. When the attenuator 248 is installed at least upstream of the main valve 243c, even in a case where the processing gas in the plasma state flows into the gas exhaust pipe 231, the processing gas will not reach the main valve 243c as it is. The processing gas in the plasma state that flows into the gas exhaust pipe 231 passes through the attenuator 248 such that the plasma energy is attenuated. Therefore, the processing gas reaches the main valve 243c after its energy is attenuated by the attenuator 248, whereby the attack on the seal 249b is suppressed by the attenuation of the plasma energy.

That is, according to the present embodiment, the presence of the attenuator 248 makes it possible to attenuate the plasma energy near the seal 249b without affecting an atmosphere in the process chamber 201. Thus, even in a case where the processing gas in the plasma state flows into the gas exhaust pipe 231, it is possible to suppress deterioration of the apparatus constituent members, specifically deterioration of the seal 249b of the main valve 243c, which may be caused by the plasma.

In particular, when the seal 249b in the main valve 243c is arranged close to the downstream opening of the second exhaust pipe 231b as in the present embodiment, there is a concern that the seal 249b may be easily deteriorated. However, even in that case, by attenuating the plasma energy by using the attenuator 248, it is possible to reliably suppress the deterioration of the seal 249b and eliminate the above-mentioned concern.

Furthermore, by installing the attenuator 248, it is possible to suppress the deterioration of the seal, and therefore it is possible to supply a sufficient amount of plasma to the exposed surface of the Si film 302 that forms the bottom of the recess 301.

### Configuration of the Attenuator

Now, a configuration of the attenuator 248 will be described by using a specific example.

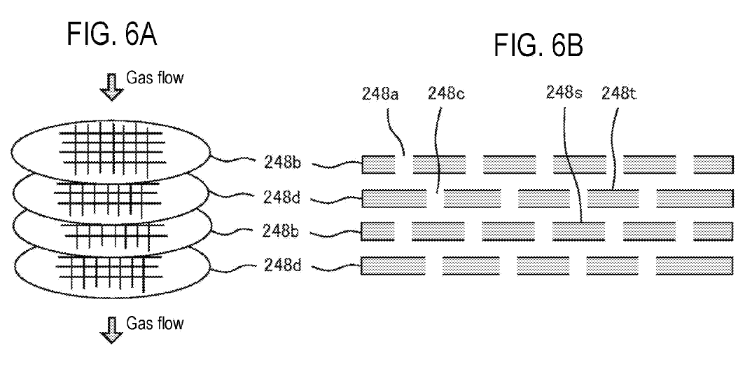

FIGS. 6A and 6B are explanatory diagrams showing an example of the configuration of the attenuator 248. As shown in FIGS. 6A and 6B, the attenuator 248 shown in this example includes at least a plate-shaped first structure 248b provided with a plurality of first through- holes 248a and a plate-shaped second structure 248d provided with a plurality of second through- holes 248c. In each of the structures 248b and 248d, plate-shaped structures between the through-holes 248a and 248c are referred to as gas collision walls 248s and 248t. The second structure 248d is installed downstream of the first structure 248b in the gas flow in the gas exhaust pipe 231. When viewed from above in the gas flow direction, the first through-holes 248a in the first structure 248b and the second through-holes 248c in the second structure 248d are configured so that the first through-holes 248a and the gas collision walls 248t of the second structure 248d at least partially overlap with each other. For example, the above configuration may be realized by arranging the first through-holes 248a and the second through-holes 248c so that they do not overlap with each other. At least one first structure 248b and at least one second structure 248d may be provided, but multiple first structures 248b and multiple second structures 248d may be provided alternately as in the illustrated example.

The attenuator 248 configured as described above is used by being arranged in a gas flow path of the gas exhaust pipe 231 so that the gas flow in the gas exhaust pipe 231 passes through the first-through-holes 248a and the second through-holes 248c sequentially. When the gas passes through the attenuator 248, a portion of the gas collides with the gas collision walls 248s of the first structure 248b. The remaining portion of the gas collides with the gas collision walls 248t of the second structure 248d because the first through-hole 248a and the gas collision walls 248t of the second structure 248d are configured to at least partially overlap each other. This makes it possible to attenuate the plasma energy of the gas passing through the attenuator 248. As long as the plasma energy can be attenuated, the configuration of the attenuator 248 is not limited to the combination of the first structure 248b and the second through-holes 248c shown in FIGS. 6A and 6B.

For example, the attenuator 248 may include a gas collision portion (or a gas collision structure) that collides with the gas flow in the gas exhaust pipe 231. Specific examples of the gas collision portion include a crank structure portion that combines multiple bent portions arranged in the gas flow direction, a curved pipe formed by a single bent portion, and the like. In a case where such a gas collision portion is provided, when the gas passes through the gas collision portion, the gas collides with an inner wall surface of the gas exhaust pipe 231 that forms the gas collision portion. This makes it possible to attenuate the plasma energy of the gas passing through the gas collision portion.

When the attenuator 248 includes the gas collision portion, the gas collision portion may include a deactivator configured to deactivate the energy of the gas in the plasma state. Specific examples of the deactivator attached to the gas collision portion include a hardware configuration (e.g., a gas guide) that increases a probability of the gas colliding with the gas collision portion, a gas adsorber attached to the gas collision portion, and the like. In a case where such a deactivator is provided, the deactivator deactivates the plasma energy, which is very effective in attenuating the plasma energy.

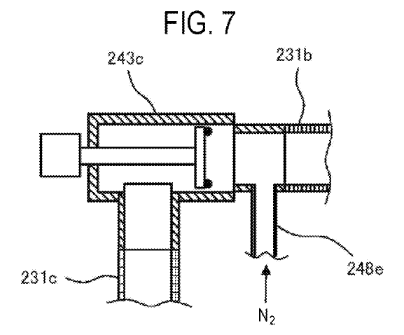

The attenuator 248 may also be configured as follows. FIG. 7 is an explanatory diagram showing another example of the configuration of the attenuator 248. As shown in FIG. 7, the attenuator 248 taken as an example herein attenuates the plasma energy by using an inert gas. That is, the attenuator 248 may include an inert gas supply portion (or an inert gas supply structure) 248e configured to enable supply of an inert gas to the gas flow in the gas exhaust pipe 231. For example, a nitrogen (N2) gas may be used as the inert gas. However, the present disclosure is not limited thereto. In addition to the N2 gas, rare gases such as an argon (Ar) gas, a helium (He) gas, a neon (Ne) gas, and a xenon (Xe) gas may also be used as the inert gas. In a case where such an inert gas supply portion 248e is provided, the inert gas may be supplied from the inert gas supply portion 248e to the gas passing through the gas collision portion so as to collide with the plasma, which makes it possible to attenuate the plasma energy.

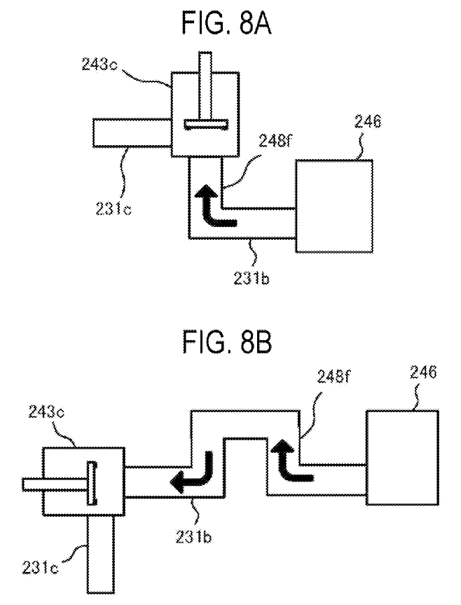

FIGS. 8A and 8B are explanatory diagrams showing another example of the configuration of the attenuator 248. As shown in FIGS. 8A and 8B, the attenuator 248 taken as an example herein attenuates plasma energy by setting the gas flow direction to a direction opposite to the direction of gravity. That is, the attenuator 248 may include an ascending portion (or an ascending structure) 248f in which the gas flow direction in the gas exhaust pipe 231 is opposite to the direction of gravity. In a case where such an ascending portion 248f is provided, the gas flow may be set to be opposite to the direction of gravity, thereby increasing collision probability of plasma in the gas. As a result, it is possible to attenuate the plasma energy of the gas.

In the present embodiment, the attenuator 248 may be constituted by any one of the above-described specific examples, or may be constituted by an appropriate combination of the above-described specific examples. That is, the attenuator 248 may be configured to attenuate the plasma energy of the processing gas flowing through the gas exhaust pipe 231 at least upstream of the main valve 243 c.

### Arrangement of the Attenuator

As previously described, the attenuator 248 configured as described above is installed at least upstream of the main valve 243c at a position in the gas exhaust pipe 231 closer to the main valve 243c than the process chamber 201. The arrangement position of the attenuator 248 on the gas exhaust pipe 231 will be described in more detail below by taking specific examples.

In the present embodiment, as shown in FIG. 1, the APC valve 242, the sub-valve 243b, and the first pump 246 are installed on the gas exhaust pipe 231 on the side of the process chamber 201. The attenuator 248 is arranged downstream of the first pump 246 (i.e., closer to the main valve 243c). That is, the attenuator 248 is installed between the first pump 246 and the main valve 243c. More specifically, the attenuator 248 is installed at the second exhaust pipe 231b, which connects the first pump 246 and the main valve 243c, among the first exhaust pipe 231 a, the second exhaust pipe 231b, and the third exhaust pipe 231 c that constitute the gas exhaust pipe 231. The first pump 246 is, for example, a turbomolecular pump. However, in a case where the attenuator 248 is installed upstream of the first pump 246, there is a concern that particles generated from the attenuator 248 may flow back into the process chamber 201 for some reasons, and that these particles may affect substrate processing. In contrast, by arranging the attenuator 248 downstream of the first pump 246, even in a case where the conductance is increased by the attenuator 248, it is possible to reduce the influence of the attenuator 248 on the atmosphere in the process chamber 201. Furthermore, in a case where the attenuator 248 is installed upstream of the first pump 246, the first pump 246 may be controlled by considering the conductance of the attenuator 248. This complicates the control, for example, when controlling the pressure. In contrast, by arranging the attenuator 248 downstream of the first pump 246, the conductance of the attenuator 248 may not be considered when controlling the first pump 246, and therefore the control is not complicated.

In the present embodiment, as shown in FIG. 5, a flow velocity fluctuation portion (or a flow velocity fluctuation structure) 248g in which a flow velocity of the gas fluctuates is present upstream of the main valve 243c in the gas exhaust pipe 231. The attenuator 248 is installed in the flow velocity fluctuation portion 248g.

The flow velocity fluctuation portion 248g is a portion in gas exhaust pipe 231 where the flow velocity of the gas flowing through gas exhaust pipe 231 increases. In other words, the flow velocity fluctuation portion 248g is a portion where the flow velocity of the gas downstream of the flow velocity fluctuation portion 248g is greater than the flow velocity of the gas upstream of the flow velocity fluctuation portion 248g. The configuration of the flow velocity fluctuation portion 248g will be described below by way of specific examples.

For example, the flow velocity fluctuation portion 248g is configured by a pipe connected to the downstream side of the first pump 246. In other words, the flow velocity fluctuation portion 248g is configured by a pipe that becomes the second exhaust pipe 231b. Since the flow velocity of the gas may be increased due to the influence of the first pump 246, such a pipe can function as the flow velocity fluctuation portion 248g.

In addition, for example, a portion 231 d where the gas flow direction in the gas exhaust pipe 231 changes is present upstream of the flow velocity fluctuation portion 248g. Such a portion 231 d may constitute a part of the first pump 246, or may constitute a part of the second exhaust pipe 231b of the gas exhaust pipe 231. In either case, such a portion 231d constitutes a bent pipe where the gas flow path in the gas exhaust pipe 231 is bent. In a case where such a portion 231 d is present, the flow velocity of the gas may increase in the pipe located downstream thereof due to the change in the gas flow direction. Therefore, such a portion 231 d can function as the flow velocity fluctuation portion 248g.

In addition, for example, a downstream end of the second exhaust pipe 231b is connected to an inlet flow path 249c that constitutes the main valve 243c. A diameter of the inlet flow path 249c (see D1 in the figure) is made to be smaller than a diameter of the second exhaust pipe 231b (see D2 in the figure). With this configuration, due to the small diameter of the inlet flow path 249c, the flow velocity of the gas in the second exhaust pipe 231b may be larger than that in the first exhaust pipe 231a. Therefore, the second exhaust pipe 231b can function as the flow velocity fluctuation portion 248g.

In addition, for example, the diameter of the second exhaust pipe 231b is made to be smaller than the diameter of the first exhaust pipe 231 a. With this configuration, due to the small diameter of the inlet flow path 249c, the gas flow velocity in the second exhaust pipe 231b may be larger than that in the first exhaust pipe 231a. Therefore, the second exhaust pipe 231b can function as the flow velocity fluctuation portion 248g.

In the present embodiment, the flow velocity fluctuation portion 248g may be constituted by any one of the above-described specific examples, or may be constituted by an appropriate combination of the above-described specific examples. In other words, the flow velocity fluctuation portion 248g may be a portion where the flow velocity of the gas flowing through the gas exhaust pipe 231 locally increases at least upstream of the main valve 243c.

In a case where the attenuator 248 is installed in the flow velocity fluctuation portion 248g as described above, the flow velocity fluctuation portion 248g exists in a portion where the flow velocity of the gas increases. Therefore, a probability of the gas colliding with the attenuator 248 increases compared to a case where the flow velocity does not increase. Accordingly, it is possible to improve an attenuation efficiency of the plasma energy for the gas passing through the attenuator 248.

For example, in a case where the flow velocity of the gas increases upstream of the main valve 243c, when the gas reaches the main valve 243c as it is, the increased flow velocity causes a large amount of plasma to attack. Therefore, there is a concern that an amount of plasma attacking the seal 249b and other components in the main valve 243c increases, which may lead to an increase in an amount of deterioration of the seal 249b and other components. However, in the present embodiment, the attenuator 248 is installed at the flow velocity fluctuation portion 248g as described above, thereby efficiently attenuating the plasma energy. In other words, even in a case where the flow velocity of the gas increases in the flow velocity fluctuation portion 248g, the attenuator 248 can deactivate the plasma before the plasma attacks the seal 249b and other components. Therefore, even in a case where the flow velocity of the gas increases upstream of the main valve 243c, it is possible to suppress deterioration of the seal 249b and other components due to the attack of plasma.

In particular, in a case where the second exhaust pipe 231b is smaller in diameter than the first exhaust pipe 231 a, the conductance of the second exhaust pipe 231b becomes larger than that of the first exhaust pipe 231 a, thereby increasing the collision coefficient. Therefore, the second exhaust pipe 231b is more likely to deactivate the plasma than the first exhaust pipe. In addition, when the second exhaust pipe 231b is smaller in diameter than the first exhaust pipe 231 a, a small attenuator 248 may be installed, which makes it possible to reduce component costs.

As described above, the attenuator 248 is installed at the second exhaust pipe 231b that connects the first pump 246 and the main valve 243c. In this case, from the viewpoint of suppressing deterioration of the seal 249b of the main valve 243c, the attenuator 248 may be located immediately before the main valve 243c. In addition, when considering that the flow velocity fluctuation portion 248g is located upstream of the main valve 243c, the attenuator 248 may be installed at the flow velocity fluctuation portion 248g. With this arrangement, the attenuator 248 can reliably suppress deterioration of the seal 249b of the main valve 243c.

### 4. Effects of The Present Embodiment

The present embodiment provides one or more of the following effects.

(a) According to the present embodiment, the attenuator 248 is installed at a position in the gas exhaust pipe 231 closer to the main valve 243c than the process chamber 201. Therefore, the energy of processing gas in a plasma state flowing through the gas exhaust pipe 231 can be attenuated without affecting the atmosphere in the process chamber 201. As a result, even in a case where the processing gas in the plasma state flows into the gas exhaust pipe 231, it is possible to suppress deterioration of the apparatus constituent members, particularly deterioration of the seal 249b of the main valve 243c, which may be caused by plasma.

(b) According to the present embodiment, the attenuator 248 is installed at the flow velocity fluctuation portion 248g. Therefore, even in a case where the flow velocity of the gas increases in the flow velocity fluctuation portion 248g, the attenuator 248 can deactivate the plasma before the plasma attacks the seal 249b, and the like. In other words, the flow velocity fluctuation portion 248g increases the probability of gas collisions in the attenuator 248, thereby increasing the attenuation efficiency of plasma energy. Accordingly, this is very useful in suppressing the deterioration of the seal 249b, and the like, which may be caused by the attack of plasma.

(c) According to the present embodiment, the flow velocity fluctuation portion 248g is constituted by, for example, the pipe connected to the downstream side of the first pump 246, the pipe existing downstream of the portion 231 d where the gas flow direction changes, the portion of the second exhaust pipe 231b which is larger in diameter than the inlet flow path 249c of the main valve 243c, the portion of the second exhaust pipe 231b which is smaller in diameter than the first exhaust pipe 231 a, or the like. Accordingly, the flow velocity of the gas can be increased in the flow velocity fluctuation portion 248g, thereby increasing the probability of gas collisions. In other words, this is very useful in increasing the efficiency of attenuation of plasma energy.

(d) According to the present embodiment, in a case where the valve body 249a and the seal 249b of the main valve 243c are arranged on an extension line of the gas exhaust pipe 231 (particularly the second exhaust pipe 231b), and the seal 249b is arranged opposite the downstream opening of the second exhaust pipe 231b, the attenuator 248 attenuates the plasma energy, which makes it to suppress the deterioration of the seal 249b, and the like, which may be caused by the attack of plasma.

(e) According to the present embodiment, the attenuator 248 is installed at the second exhaust pipe 231b, and therefore the attenuator 248 is arranged downstream of the first pump 246. Accordingly, even in a case where the conductance is increased by the attenuator 248, it is possible to reduce the influence of the attenuator 248 on the atmosphere in the process chamber 201. In addition, the conductance of the attenuator 248 may not be considered when controlling the first pump 246, and therefore the control is not complicated.

(f) According to the present embodiment, the second exhaust pipe 231b is smaller diameter than the first exhaust pipe 231 a. Therefore, the conductance of the second exhaust pipe 231b is larger than that of the first exhaust pipe 231 a, which increases the collision coefficient in the second exhaust pipe 231b. Accordingly, in a case where the attenuator 248 is installed at the second exhaust pipe 231b, it becomes easier to deactivate the plasma compared to a case where the attenuator 248 is installed at the first exhaust pipe 231 a. In addition, in a case where the second exhaust pipe 231b is smaller in diameter than the first exhaust pipe 231a, a small attenuator 248 can be installed, which makes it possible to reduce component costs.

(g) According to the present embodiment, the attenuator 248 is constituted, for example, by including the first structure 248b and the second structure 248d, including the gas collision portion that collides with the gas flow in the gas exhaust pipe 231, including the deactivator attached to the gas collision portion, including the inert gas supply portion 248e that can supply an inert gas to the gas flow, including the ascending portion 248f in which the gas flow direction in the gas exhaust pipe 231 is opposite to the direction of gravity, or the like. The attenuator 248 configured as described above may increase the collision probability of plasma in the gas, and can deactivate the plasma to reliably attenuate the energy of the plasma.

(h) According to the present embodiment, the plasma generator includes the resonance coil 212 configured to be capable of generating plasma in the process chamber 201, and ICP generation is performed by the resonance coil 212. When using ICP, a large number of radicals may be generated. Therefore, processing can be performed appropriately, for example, even when processing a wafer 200 including a high-aspect-ratio recess 301 on a surface thereof. However, the generation of a large number of radicals by using ICP may increase an amount of deterioration caused by an amount of radicals. However, according to the present embodiment, there is installed the attenuator 248 that attenuates the plasma energy. Accordingly, even when using ICP, it is possible to suppress deterioration of the apparatus constituent members, specifically deterioration of the seal 249b of the main valve 243c, which may be caused by plasma.

### Second Embodiment

Next, a second embodiment of the present disclosure will be described specifically. Here, differences from the above-described first embodiment will be mainly described, and other points will not be described.

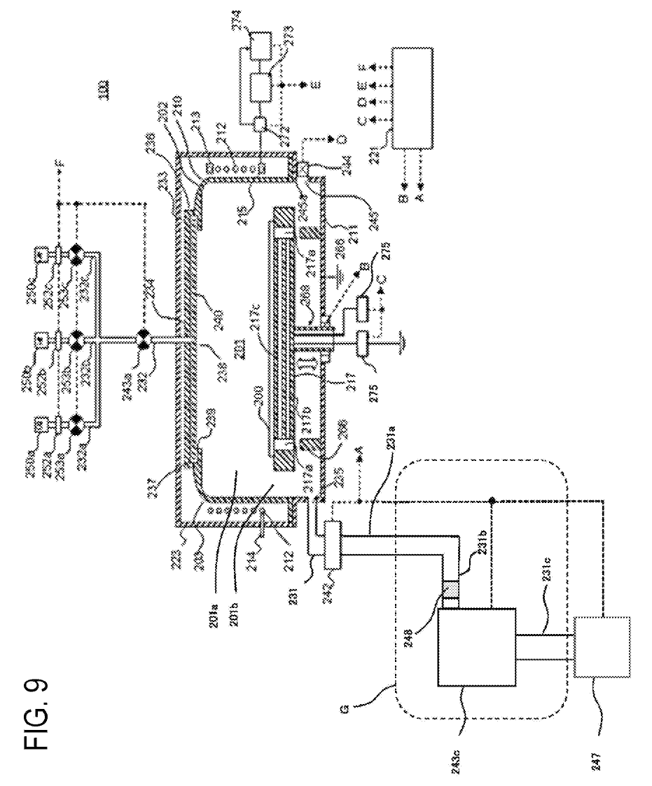

The substrate processing apparatus 100 according to the present embodiment differs from the substrate processing apparatus according to the first embodiment in terms of a configuration of the exhauster. FIG. 9 is a schematic diagram of the substrate processing apparatus according to the second embodiment.

The exhauster according to the present embodiment is configured to include a gas exhaust port 235, a gas exhaust pipe 231, and an APC valve 242. The exhauster may further include a main valve 243c and a second pump 247. As described above, in the present embodiment, the exhauster is not provided with the sub-valve 243b and the first pump 246 described in the first embodiment.

However, the attenuator 248 and the flow velocity fluctuation portion 248g are configured in the same manner as in the first embodiment. That is, the attenuator 248 is installed at a position in the gas exhaust pipe 231 closer to the main valve 243c than to the process chamber 201, more specifically, at the second exhaust pipe 231b, and is located upstream of (specifically just before) the main valve 243c. At this position, the attenuator 248 attenuates the plasma energy of the gas passing therethrough. Also in the present embodiment, at the gas exhaust pipe 231, a flow velocity fluctuation portion 248g exists upstream of the main valve 243c. The attenuator 248 is installed at the flow velocity fluctuation portion 248g.

The present embodiment as described above also provides one or more of the effects described in the first embodiment.

### Third Embodiment

Next, a third embodiment of the present disclosure will be described specifically. Here, differences from the above-described first embodiment or second embodiment will be mainly described, and other points will not be described.

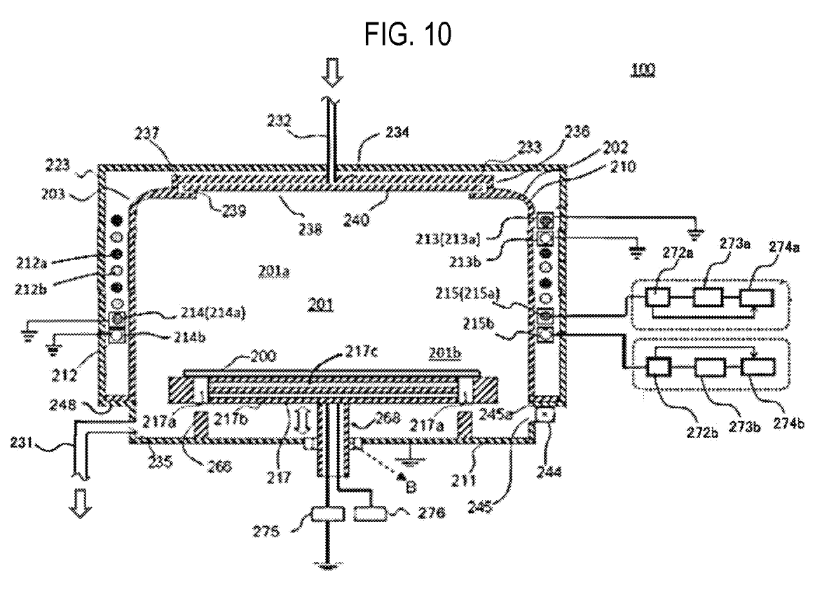

The substrate processing apparatus 100 described in the present embodiment differs from the first embodiment or the second embodiment in terms of a configuration of the plasma generator. FIG. 10 is a configuration diagram of main components of the substrate processing apparatus according to the third embodiment.

In the present embodiment, a spiral first resonance coil (hereinafter also simply referred to as a "first coil") 212a and a spiral second resonance coil (hereinafter also simply referred to as a "second coil") 212b adjacent to the first coil 212a are installed at an outer periphery of the process chamber 201, i.e., at the outside of the sidewall of the upper container 210, so as to surround the process chamber 201. A RF sensor 272a, a high-frequency power supply 273a, and a matcher 274a are connected to the first coil 212a, and ICP is generated in the process chamber 201 when high-frequency power is supplied to the first coil 212a. In addition, an RF sensor 272b, a high-frequency power supply 273b, and a matcher 274b are connected to the second coil 212b, and ICP is generated in the process chamber 201 when high-frequency power is supplied to the second coil 212b.

That is, in the present embodiment, the plasma generator is configured to include a first coil 212a configured to be capable of generating plasma in the process chamber 201, and a second coil 212b adjacent to the first coil 212a and configured to be capable of generating plasma in the process chamber 201. Other configurations may be the same as those of the substrate processing apparatus according to the first embodiment or the second embodiment.

According to the present embodiment of such a configuration, the first coil 212a and the second coil 212b function as a double coil, thereby increasing the number of radicals in the ICP. This is very useful in that processing can be performed appropriately, for example, even in a case where a large number of radicals are required, such as when processing a wafer 200 including a high-aspect-ratio recess 301 on a surface thereof.

Furthermore, even in a case where an amount of radicals in the ICP increases, the presence of the attenuator 248 can suppress deterioration of the apparatus constituent members, particularly deterioration of the seal 249b of the main valve 243c, which may be caused by plasma. In other words, the present embodiment also provides one or more of the effects described in the first embodiment or the second embodiment.

### Fourth Embodiment

Next, a fourth embodiment of the present disclosure will be described specifically. Here, differences from the above-described first embodiment, second embodiment or third embodiment will be mainly described, and other points will not be described.

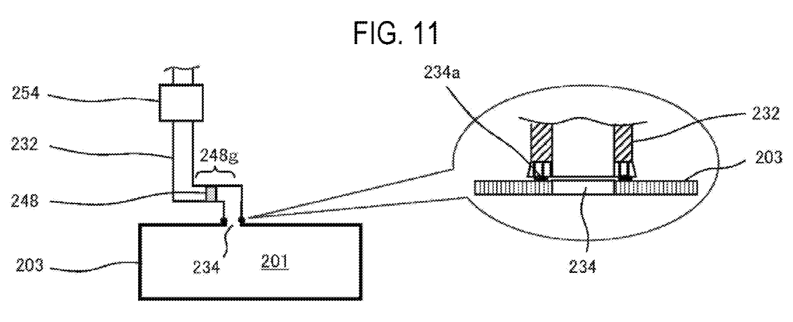

The substrate processing apparatus 100 described in the present embodiment differs from the first embodiment, the second embodiment or the third embodiment in terms of configurations of the gas supplier and the plasma generator. FIG. 11 is a configuration diagram of main components of the substrate processing apparatus according to the fourth embodiment.

In the present embodiment, a remote plasma unit (RPU) 254 is installed at the gas supply pipe 232 constituting the gas supplier. The RPU 254 converts the processing gas flowing through the gas supply pipe 232 into a plasma state.

That is, the RPU 254 functions as a plasma generator (plasma generation mechanism) according to the present embodiment. Therefore, in the present embodiment, neither the resonance coil 212 described in the first embodiment nor the first coil 212a and the second coil 212b described in the third embodiment is installed.

According to the present embodiment of such a configuration, when processing the wafer 200 in the process chamber 201, the processing gas supplied from the gas supply pipe 232 into the process chamber 201 is converted into a plasma state by the RPU 254.

In this case, it may not be easy to precisely control the energy level , the radical amount, and the like of plasma in the RPU 254. Therefore, when attempting to secure a sufficient energy level for processing the wafer 200, the plasma energy may actually be excessive. In a case where a gas is supplied into the process chamber 201 through the gas introduction port 234 with such excessive energy, the plasma may attack, for example, the seal 234a such as an O-ring that seals a connection between the process container 203 and the gas supply pipe 232, which may result in deterioration of the seal 234a.

In view of this, in the present embodiment, the attenuator 248 is installed at the gas supply pipe 232. More specifically, the attenuator 248 is installed at the gas supply pipe 232 upstream of the connection between the gas supply pipe 232 and the process container 203 that constitutes the process chamber 201. The attenuator 248 may be the same as that of the first embodiment, the second embodiment, or the third embodiment.

The attenuator 48 may be installed at the flow velocity fluctuation portion 248g as in the first embodiment, the second embodiment, or the third embodiment. That is, in the present embodiment, the flow velocity fluctuation portion 248g may exist in the gas supply pipe 232.

According to the present embodiment of the above configuration, the attenuator 248 is installed at the gas supply pipe 232 upstream of the connection between the gas supply pipe 232 and the process container 203, which makes it possible to attenuate the energy of the processing gas in a plasma state flowing through the gas supply pipe 232. As a result, for example, even in a case where the energy of plasma generated by the RPU 254 becomes excessive, by attenuating the energy of plasma by using the attenuator 248, it is possible to suppress the deterioration of the apparatus constituent members, specifically the deterioration of the seal 234a at the connection between the process container 203 and the gas supply pipe 232, which may be caused by the plasma, without affecting the atmosphere in the process chamber 201.

That is, the present embodiment also provides one or more of the effects described in the first embodiment, the second embodiment, or the third embodiment, except for the difference between the gas supplier side and the exhauster side.

### Other Embodiments

Although the embodiments of the present disclosure are specifically described above, the present disclosure is not limited to the above-described embodiments. The above-described embodiments may be combined as appropriate. Various modifications may be made without departing from the spirit of the present disclosure.

For example, in the above-described embodiments, the case where an oxidation process is performed on the wafer 200 in the substrate processing process are described by way of example. However, the present disclosure is not limited thereto. In other words, as long as the substrate processing process is performed by using plasma, it may be a film formation process or a process for forming a film containing a metal, in addition to the oxidation process. In other words, the present disclosure may be suitably applied to other substrate processing processes, such as an oxidation process, a nitriding process, a film formation process, an annealing process, a diffusion process, and a lithography process. Furthermore, the present disclosure may also be suitably applied to other substrate processing apparatuses, such as an annealing apparatus, an oxidation apparatus, a nitriding apparatus, an exposure apparatus, a coating apparatus, a drying apparatus, a heating apparatus, and a plasma processing apparatus. The present disclosure may also incorporate a mixture of these apparatuses. Moreover, it is possible to replace a part of the configuration of one embodiment with the configuration of another embodiment, or to add a part of the configuration of one embodiment to the configuration of another embodiment. Further, a part of the configuration of each embodiment, addition, deletion, or replacement with another configuration is also possible.

Further, the processing gas to be converted into a plasma state is not limited to the O- containing gas and the H-containing gas, and may be other types of gases depending on the processing to be performed in the substrate processing process.

According to the present disclosure in some embodiments, it is possible to suppress deterioration of apparatus constituent members caused by plasma.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:a process chamber in which a substrate is processed with a gas;a plasma generator configured to convert the gas into a plasma state;a supply pipe installed at an upstream side of the process chamber;an exhaust pipe installed at a downstream side of the process chamber;a valve installed at a downstream side of the exhaust pipe; andan attenuator configured to attenuate an energy of the gas in the plasma state, the attenuator being installed at the exhaust pipe at a position closer to the valve than the process chamber, or installed at an upstream side of a connection between the supply pipe and the process chamber.

2. The substrate processing apparatus of claim 1, wherein the attenuator is installed at a flow velocity fluctuation structure where a flow velocity of the gas fluctuates.

3. The substrate processing apparatus of claim 2, wherein the flow velocity fluctuation
structure is a portion in the exhaust pipe or the supply pipe where the flow velocity of the gas increases.

4. The substrate processing apparatus of claim 2, wherein the flow velocity fluctuation structure is a pipe connected to a downstream side of a first pump installed at a gas flow path of the exhaust pipe.

5. The substrate processing apparatus of claim 2, wherein a portion where a gas flow direction is changed in the supply pipe or a portion where a gas flow direction is changed in the exhaust pipe is provided at an upstream side of the flow velocity fluctuation structure.

6. The substrate processing apparatus of claim 1, wherein the valve includes a valve body and a seal, and the valve body and the seal are arranged at positions on an extension line of the supply pipe or the exhaust pipe.

7. The substrate processing apparatus of claim 6, wherein the seal is arranged at a position facing a downstream opening of the supply pipe or the exhaust pipe.

8. The substrate processing apparatus of claim 6, wherein an inlet flow path constituting the valve is configured such that a diameter of the inlet flow path is smaller than a diameter of the supply pipe or the exhaust pipe.

9. The substrate processing apparatus of claim 1, wherein an interior of the exhaust pipe is configured to be in fluid communication with an interior of the process chamber through an exhaust port installed at the process chamber,wherein the exhaust pipe includes a first exhaust pipe configured to connect a first pump installed at a gas flow path of the exhaust pipe to the exhaust port and a second exhaust pipe configured to connect the first pump to the valve, andwherein the attenuator is installed at the second exhaust pipe.

10. The substrate processing apparatus of claim 9, wherein the second exhaust pipe is configured such that a diameter of the second exhaust pipe is smaller than a diameter of the first exhaust pipe.

11. The substrate processing apparatus of claim 1, wherein the attenuator includes at least a
first structure including a plurality of first through-holes and a second structure installed at a downstream side of the first structure and including a plurality of second through-holes and gas collision walls installed between the second through-holes, andwherein the first through-holes and the gas collision walls are arranged so as to at least partially overlap with each other.

12. The substrate processing apparatus of claim 1, wherein the plasma generator includes a coil configured to be capable of generating plasma in the process chamber.

13. The substrate processing apparatus of claim 1, wherein the plasma generator includes a first coil configured to be capable of generating plasma in the process chamber and a second coil adjacent to the first coil and configured to be capable of generating plasma in the process chamber.

14. The substrate processing apparatus of claim 1, wherein the attenuator includes a gas collision structure configured to collide with a gas flow of the gas.

15. The substrate processing apparatus of claim 14, wherein the gas collision structure
includes a deactivator configured to deactivate the energy of the gas in the plasma state.

16. The substrate processing apparatus of claim 1, wherein the attenuator includes an inert gas supply structure configured to enable supply of an inert gas to the gas.

17. The substrate processing apparatus of claim 1, wherein the attenuator includes an ascending structure in which a gas flow direction of the gas is opposite to a direction of gravity.

18. A method of processing a substrate by using a substrate processing apparatus, which includes a process chamber in which the substrate is processed with a gas, a plasma generator configured to convert the gas into a plasma state, a supply pipe installed at an upstream side of the process chamber, an exhaust pipe installed at a downstream side of the process chamber, a valve installed at a downstream side of the exhaust pipe, and an attenuator configured to attenuate an energy of the gas in the plasma state, the attenuator being installed at the exhaust pipe at a position closer to the valve than the process chamber, or installed at an upstream side of a connection between the supply pipe and the process chamber, the method comprising:processing the substrate in the process chamber.

19. A method of manufacturing a semiconductor device, comprising the method of claim 18.

20. A non-transitory computer-readable recording medium storing a program that causes, by a computer, a substrate processing apparatus, which includes a process chamber in which a substrate is processed with a gas, a plasma generator configured to convert the gas into a plasma state, a supply pipe installed at an upstream side of the process chamber, an exhaust pipe installed at a downstream side of the process chamber, a valve installed at a downstream side of the exhaust pipe, and an attenuator configured to attenuate an energy of the gas in the plasma state, the attenuator being installed at the exhaust pipe at a position closer to the valve than the process chamber, or installed at an upstream side of a connection between the supply pipe and the process chamber, to perform a process comprising:processing the substrate in the process chamber.
